(19) United States
(12) Patent Application Publication
(10) Pub. No.: US 2026/0266672 A1
(43) Pub. Date: Sep. 10, 2026

(54) ROLLER WITH SHIELDING FOR SENSORS

(71) Applicants: VOITH PATENT GMBH, Heidenheim (DE); JOANNEUM RESEARCH FORSCHUNGSGESELLSCHAFT MBH, Graz (AT)

(72) Inventors: Stefan POLLASCHEK, Traiskirchen (AT); Martin BREINEDER, Natschbach (AT); Andreas TSCHEPP, Kumberg (AT); Stephan RUTTLOFF, Anger (AT); Martin ZIRKL, Wilfersdorf (AT); Barbara STADLOBER, Graz (AT)

(21) Appl. No.: 19/657,228

(22) Filed: Apr. 24, 2026

Related U.S. Application Data
(63) Continuation of application No. PCT/EP2024/076055, filed on Sep. 18, 2024.

(30) Foreign Application Priority Data
Oct. 27, 2023 (DE) 10 2023 129 720.1

(51) Int. Cl. G01L 5/00; D21F 3/06; D21F 3/08; G01L 1/16; H05K 9/00

(52) U.S. Cl. CPC G01L 5/0004; D21F 3/06; D21F 3/08; G01L 5/0085; H05K 9/0084; G01L 1/16

(57) ABSTRACT

A roller for a web processing machine wherein the roller has a roller cylinder with a cylindrical roller core, a roller cover surrounding the roller core, and an outer surface. The roller cover has one or more roller cover layers in the radial direction and contains sensors. An electrically conductive shielding is arranged radially between the sensors and the outer surface; a web processing machine comprising the sensor roller and a counter-roller arranged parallel to the sensor roller with a treatment gap therebetween. Each of the sensors of the sensor roller can detect the pressure exerted on the sensor roller as it passes through the treatment gap.

### CROSS-REFERENCE TO RELATED APPLICATION

This application is a continuation, under 35 U.S.C. § 120, of copending International Patent Application PCT/EP2024/076055, filed Sep. 18, 2024, which designated the United States; this application also claims the priority, under 35 U.S.C. § 119, of German Patent Application DE 10 2023 129 720.1, filed Oct. 27, 2023; the prior applications are herewith incorporated by reference in their entirety.

### FIELD AND BACKGROUND OF THE INVENTION

The present invention relates to a roller for a web processing machine and to a web processing machine comprising the roller.

WO 2013/104600 A1 and U.S. Pat. No. 5,562,027 disclose rollers for a paper machine that are equipped with sensors for measuring pressure in a roller gap. WO 2013/104600 A1 discloses fiber-optic sensors, while U.S. Pat. No. 5,562,027 uses conventional piezoelectric sensors. Printed piezoelectric films for pressure detection are known from WO 2014/037016 A1. FI 12489 U1 discloses a roll for a paper machine with a sensor structure printed beneath the roll surface.

In a roller equipped with sensors for pressure detection, the quality of the read signal deteriorates under certain conditions. For example, this occurs when the roller forms a roller pair with another roller, with a treatment gap in between, and the roller pair is operated in a dry state. The inventors have recognized that this degradation in signal quality is caused by electrostatic charging of the roller contact surface.

### SUMMARY OF THE INVENTION

It is accordingly an object of the present invention to provide a roller with an improved sensor system that delivers reliable, high-quality sensor readings even under difficult operating conditions. The problems and disadvantages of the prior art are solved by providing a roller for a web processing machine, wherein the roller includes an electrically conductive shield, as well as a web processing machine comprising the roller.

With the foregoing and other objects in view there is provided, in accordance with the invention a roller for a web processing machine, wherein the roller comprises a roller cylinder having a cylindrical roller core, a roller cover surrounding the roller core, and an outer surface, wherein the roller cover consists of one or more roller cover layers in the radial direction and contains sensors, and an electrically conductive shielding is arranged in the radial direction between the sensors and the outer surface.

In a further embodiment, the sensors are arranged beneath the functional layer of the roller, wherein the thickness of the functional layer is preferably 3 mm to 40 mm.

In an additional embodiment, the web processing machine is a paper web processing machine.

In another further embodiment, the length of the roller is 1 to 20 m, the diameter of the roller core is 5 to 100 mm, the thickness of the roller cover is 5 to 50 mm, the roller cover has more than 5, preferably more than 10 sensors, and the thickness of the shielding is 1 μm to 10 mm.

In a further embodiment, the sensors are pressure sensors.

In an advantageous embodiment, the sensors are piezoelectric sensors.

In another further embodiment, the sensors are arranged on the roller core or between two roller cover layers.

In another additional embodiment, the sensors are separated from the shielding by an insulator.

In another advantageous embodiment, the sensors are applied as a sensor layer to the roller core, to a roller cover layer, to the insulation, or to a sensor film.

In a further embodiment, the sensor layer comprises the sensors and electrical conductors.

In an additional embodiment, the thickness of the sensor layer is 1 μm to 50 μm.

In an advantageous embodiment, the sensors are arranged on the shielding and are separated from it by an insulation layer.

In another further embodiment, the shielding is a metal foil, the insulation is printed onto the metal foil, and the sensors are printed onto the insulation.

In another additional embodiment, the thickness of the metal foil, the insulation, and the sensors is 1 μm to 50 μm, respectively.

In another advantageous embodiment, the sensor film is a polymer film.

In a further embodiment, the thickness of the polymer film is 50 μm to 3 mm.

In an additional embodiment, the sensors are printed or the sensor layer is printed.

In a further embodiment, the shielding is electrically conductive because it contains metal-containing or carbon-containing materials.

In an additional embodiment, the shielding is a roller cover layer containing electrically conductive material, a shielding film, a shielding mesh, or a shielding layer applied to the sensors or the insulation on the sensors.

In another further embodiment, the electrically conductive material is a fabric or contains fibers or particles, preferably carbon black particles or nanotubes, embedded in the roller cover layer.

In a further embodiment, the thickness of the shielding foil is 1 μm to 100 μm.

In an advantageous embodiment, the shielding foil is a metal foil having a thickness of 1 μm to 50 μm.

In another further embodiment, wherein the shielding layer covers the sensors and adjacent areas.

In another additional embodiment, the shielding layer is printed.

In another advantageous embodiment, the thickness of the shielding layer is 1 μm to 50 μm.

In a further embodiment, the sensors are printed on a sensor film, an insulating layer is printed on the sensors, and the shielding layer is printed on the insulating layer, wherein the thickness of the sensors, the insulating layer, and the shielding layer is in each case 1 μm to 50 μm, preferably 5 μm to 40 μm.

In an additional embodiment, the roller core is electrically conductive and makes electrical contact with the shielding.

In an advantageous embodiment, the shielding is in contact with the roller core.

In another further embodiment, the roller core is electrically grounded.

In another additional embodiment, the shielding is a shielding foil or an electrically conductive roller coating layer, and the sensors are separated from the shielding by an insulator.

In another advantageous embodiment, either the shielding is a foil that extends beyond the roller cylinder and makes electrical contact with the roller core, or the sensors are arranged between the roller core and an electrically conductive roller covering layer, and the roller core and the electrically conductive roller cover layer are in electrical contact between the sensors.

In a further embodiment, the roller core extends longitudinally beyond the roller cylinder.

In an additional embodiment, the signals generated in the sensors are transmitted via a signal line to a sensor data unit.

In another further embodiment, the sensors differ from one another in their position in the circumferential direction of the roller cylinder.

In another advantageous embodiment, a single signal line transmits the signals from several or all of the sensors to the sensor data unit.

In another additional embodiment, a position sensor is configured for detecting the rotational angle of the roller is arranged on one of the end faces of the roller.

In a further embodiment, the position sensor and the sensor data unit are arranged on the same end face of the roller and are connected to each other via a data line.

With the foregoing and other objects in view there is provided, in accordance with the invention, a web processing machine comprising a roller according to any of the embodiment described above, configured as a sensor roller, and a counter-roller arranged parallel to the sensor roller with a treatment gap therebetween, wherein each of the sensors of the sensor roller can detect the pressure exerted on the sensor roller as it passes through the treatment gap.

The shielding in the roller according to the invention improves the quality of the signals detected by the sensors in the roller.

Other features which are considered as characteristic for the invention are set forth in the appended claims.

Although the invention is illustrated and described herein as embodied in a roller with shielding for sensors, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments.

### BRIEF DESCRIPTION OF THE FIGURES

FIG. 1 shows a schematic representation of an embodiment of a roller for a web processing machine.

FIG. 2 shows a schematic representation of the layering of the roller taken at “II” from FIG. 1.

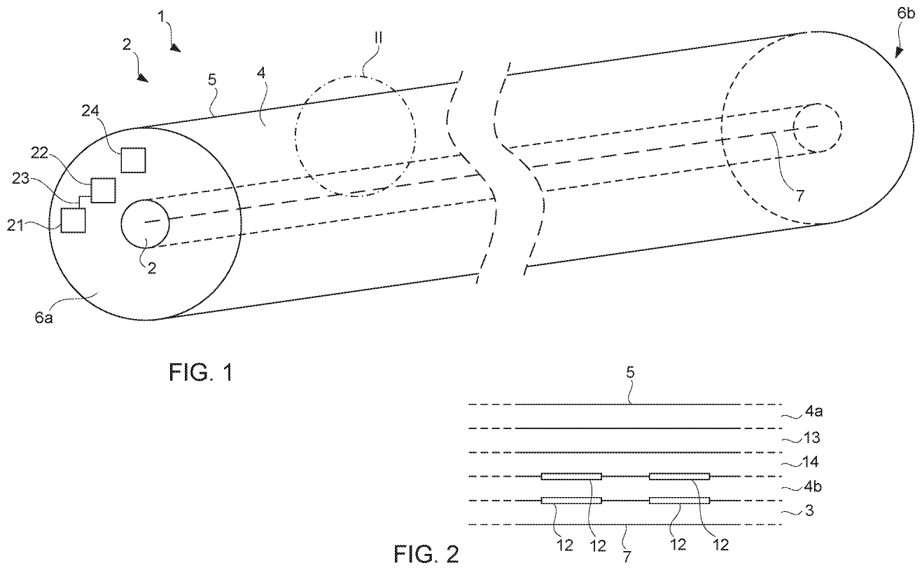

### DETAILED DESCRIPTION OF THE INVENTION

The roller 1 of the invention for a web processing machine is hereinafter sometimes simply referred to as “the roller.” Similarly, the components of the roller 1 of the invention or the web processing machine are hereinafter sometimes simply referred to as “the sensors,” “the shielding,” and the like.

The roller 1 comprises a roller cylinder 2 that includes a cylindrical roller core 3, a roller cover 4 surrounding the roller core 3, and an outer surface 5, wherein the roller cover 4 consists of one or more roller cover layers 4a, 4b, . . . 4n in the radial direction. The roller core 3 is made of metal, for example. The roller cover 4 is made of polyurethane, rubber, a composite material, or a fiber-reinforced composite, for example.

The roller 1 can be used for pressure detection in a web processing machine. Examples of webs include nonwovens, fabrics, films, paper webs, or metal webs. The machine may be suitable for the following web processing applications:
Coating processes, for example for encapsulations, particularly in photovoltaics, in packaging technology, particularly food packaging, battery manufacturing, particularly in the production of anodes, cathodes, and separators, for OLEDs and optical coatings, as well as for anti-scratch coatings, anti-dust coatings, and electrostatic coatings;
Bonding processes, laminating processes, calendering processes;
Lamination, for example in the production of encapsulations, multi-layered composites, PCB laminates, packaging or pouches, batteries and fuel cells, wound capacitors, flexible electronic circuits and solar cells, displays, and for medical applications, particularly for the production of patches or test strips;
Assembly processes, for example in the manufacture of electronic components;
Rolling mills;
Conveyor belts, for example for recycling or sorting;
Extrusion lines, for example for film production;
Printing processes, such as graphic printing, newspaper or paper printing, label printing, currency printing, for printed electronics, offset printing, gravure printing, flexographic printing, engraving printing, OLED, and optical applications;
Imprinting processes, such as nanoimprint lithography or hot stamping, particularly for anti-reflective coatings;
Web path optimization, for example, for measuring web tension or tensile force, or in vacuum coating, particularly for metal coatings, including for food products;
Textile finishing, particularly through printing, coating, or dyeing;
Steel and metal strip production; and
Condition monitoring for large substrates, particularly wind turbines.

A paper machine, as an example of a web processing machine, produces paper webs over 10 meters wide. The rolls required for this are even wider, as they extend beyond the paper web on both sides. To process the paper web, pairs of rolls are used with a treatment gap between them. A treatment gap can, for example, be a press gap for mechanical dewatering, a calender gap for smoothing, or a coating gap for pressing a starch solution into the web to increase its strength.

At least one of the rolls in the roll pair contains sensors 12 for pressure detection. Since a pressure profile is typically to be detected across the entire working width, a large number of sensors 12 can, for example, be fabricated on a sensor film of at least this length of the roll and applied to the roll.

In the roller 1, the sensors 12, the insulation 14, and the shielding 13 may be applied as layers onto another layer or a substrate. Here, the term “applied” means that the starting material of the desired layer is applied in an applicable form, for example in liquid or paste form, and is subsequently solidified into the desired layer. The application may be performed by printing, vapor deposition, or spraying, with printing being preferred, such that the term “applied” herein always preferably means “printed.” On the other hand, when printed layers are described herein, this is done solely for the sake of simplicity, and the layers may equally be applied by another method.

In this context, components may be referred to in the singular, for example, “a sensor layer” and “the shielding.” These terms are not intended to exclude a plural and therefore mean “at least one sensor layer” or “the at least one shielding.” Accordingly, expressions such as “comprises . . . a sensor layer” and “comprises . . . the shielding” or similar formulations are synonymous with “comprises . . . at least one sensor layer” and “comprises . . . the at least one shielding,” respectively. This applies accordingly to the other components of the roller 1 or the web processing machine.

For example, the roller 1 contains 5 to 20 sensors 12. The sensors 12 are distributed over the entire length of the roller 1. In other words, the sensors 12 differ from one another in their position along the roller's rotational axis 7. Additionally, they may differ from one another in their position along the circumference of the roller cylinder 2. The sensors 12 respond to at least one change in an environmental property selected from the group consisting of pressure, temperature, and light intensity. They may therefore be pressure, temperature, and/or optical sensors 12, with a pressure sensor 12 being preferred. The pressure sensor 12 may be a piezoelectric sensor.

The sensors 12 may be embedded in a material of a roller cover layer 4a, 4b, . . . 4n, for example in a polymer. However, they may also be applied as a thin sensor layer 12 to a substrate. Examples of substrates include films, preferably flexible plastic films. The use of a printed sensor layer 12 is highly advantageous for many applications, such as use in rotating rollers. On the one hand, it is inexpensive to manufacture. On the other hand, due to its flat construction and flexible film structure, the sensor layer 12 can be very well secured in a curved roller without the risk of delamination. With conventional sensors, this risk is quite high, since the roller 1 is subjected to significant continuous rolling stress during operation when it forms a nip with a second roller.

The sensor may be a layered sensor comprising a first electrically conductive layer, a layer of a ferroelectric polymer, and a second electrically conductive layer in that order. Preferably, the ferroelectric polymer layer, the electrically conductive layers, and the conductor are printable.

The shielding 13 is electrically conductive. In this context, the term “electrically conductive” also includes the meaning of “electrically dissipative.” In any case, the shielding 13 must be sufficiently conductive to achieve the desired goal of consistent signal quality by preventing electrostatic charging of the assembly. For example, the resistance of the shielding 13 layer is less than 10⁹ ohms.

The shielding 13 is arranged radially between the sensors 12 and the outer surface 5. This means that, with respect to a sensor, the shielding 13 is arranged such that, in a circular cross-section of the roller cylinder 2, the shielding 13 and the sensor are intersected by the same radial line.

In the roller 1, electrostatic interference is reduced both by the distance of the sensors 12 from the roller surface and by the electrically conductive shielding 13. Since the thickness of the roller cover 4 is usually between 15 mm and 30 mm, electrostatic interference can already be reduced by applying the sensors 12 to the roller core 3 or to a layer beneath the roller surface. For example, a base layer of the roller cover 4 with a thickness of 3 mm to 7 mm can be applied to the roller core 3. The sensor film can then be attached to this base layer. The remainder of the roller cover 4 can then be applied over the sensor film as a functional layer. A functional layer is the outermost layer of the roller's surface and serves as the contact surface for the material web. The thickness of the functional layer can range from 12 mm to 25 mm.

The distance between the shielding 13 and the sensors 12 should be small so that the shielding effect is as effective as possible. For technical reasons, there must be insulation 14 between the shielding 13 and the sensor electronics. Therefore, the required insulation 14 thickness determines the minimum distance. The shielding 13 may have any planar structure; it may be a continuous layer without through-holes or may have a grid structure, mesh structure, or fabric structure. The shielding 13 is preferably designed as a shielding layer 13, whereby the following embodiments are possible.

In one embodiment, the shielding 13 may be a film that is, for example, adhered or laminated. The film may be a metal foil, such as aluminum foil, or a film made of a conductive polymer. An example of a conductive polymer is PEDOT:PSS (PEDOT:PSS:poly(3,4-ethylenedioxythiophene):polystyrene sulfonate). Alternatively, a grid or mesh structure may be used instead of a continuous film, for example to save weight.

In a further embodiment, the shielding 13 can be applied as a layer to a substrate, for example by printing. If the electronics are being printed anyway, it can be advantageous to print the shielding layer 13 as well. In this case, there is great flexibility regarding the shape, size, and thickness of the shielding 13. For example, the shielding 13 need only be printed in the area of the electronic elements and the conductors. Printable materials that can be used include electrically conductive polymers, such as PEDOT:PSS, or printable metallic nanowires, carbon, and/or Ag. However, the applied shielding layer 13 may also be a layer of an electrically conductive adhesive, for example an acrylate adhesive filled with Ag nanoparticles, and thus fulfill the additional function of firmly bonding two layers or substrates.

In an additional embodiment, the shielding 13 is based on a non-conductive material, i.e., it contains at least 50 mass percent, more preferably at least 80 mass percent, of this material. For example, the shielding 13 may be a polymer-based film in which conductive substances are embedded such that a shielding film 13 is formed that is conductive as a whole. Examples of such substances include carbon nanotubes or conductive carbon black.

In yet a further embodiment, the shielding 13 may have an additional function, possibly as a primary function, in addition to the shielding effect. For example, carbon or metal filaments may be incorporated as a fabric in a roller cover layer 4a, 4b, . . . 4n made of an epoxy resin, wherein the filamentary materials also impart the strength necessary for the actual function of the roller cover layer 4a, 4b, . . . 4n.

The shielding 13 must cover at least the electrically conductive elements of the sensors 12. Preferably, the shielding 13 also extends laterally beyond these elements. For example, the shielding 13 extends beyond the sensor by at least the distance between the shielding 13 and the sensor 12. When using a foil, this is usually the case anyway. However, with printed shielding 13 as described in (ii), very thin and small-area shields can also be produced. For example, an insulating layer 14 with a thickness of 15 μm is applied to the printed electronics. The shielding layer 13 is printed onto this insulating layer 14. In this case, the shielding layer 13 should be wide enough to cover the electronic components and extend at least 15 μm beyond them on the sides.

The shielding 13 can be very thin. For example, commercially available aluminum foils with a thickness of 4 μm to 20 μm, particularly 10 μm to 15 μm, are sufficient for a shielding effect.

The insulation 14 consists of a material that electrically isolates the sensors 12 from the shielding 13. To fulfill this function, the insulation 14 must have a higher electrical resistance than the shielding 13. An example of a material for the insulation 14 is a non-conductive polymer. Preferably, the insulation 14 is printable as a layer. The insulation 14 may also be an adhesive layer that, for example, bonds a foil substrate printed with sensors 12 to the shielding layer 13.

In one embodiment, the roller core 3 is electrically conductive, for example metallic, and makes electrical contact with the shielding 13. The shielding 13 may be a film that extends beyond the sensors 12 or extends longitudinally beyond the roller cylinder 2 and makes electrical contact with the roller core 3. Alternatively, the sensors 12 may be arranged between the roller core 3 and an electrically conductive roller cover layer 4a, 4b, . . . 4n, wherein the roller core 3 and the electrically conductive roller cover layer 4a, 4b, . . . 4n are in electrical contact between the sensors 12. The roller core 3 may be electrically grounded.

When a sensor passes through the treatment gap, a signal is generated that is routed via a signal line to one end face 6a, 6b of the roller 1, where it is then processed by a sensor data unit 21 and, if necessary, transmitted to an external evaluation unit. Such a sensor data unit 21 is preferably mounted on the end face 6a, 6b, i.e., the cover of the roller 1.

If the sensors 12 are mounted parallel to the roller axis 7, all sensors 12 pass through the treatment gap simultaneously. To assign the signals to the correct sensors 12, each sensor then requires its own signal line. However, this necessitates very wide sensor strips when using many sensors 12.

Therefore, the sensor strip is preferably applied to the roller 1 or the roller core 3 in the form of a slight spiral, so that each sensor differs from every other sensor both in its position in the axial direction 7 of the roller 1 and in its position in the circumferential direction of the roller 1. Alternatively, the sensors 12 may differ from one another in their position in the rotational axis direction 7 of the roller 1, and not all sensors 12 need to have the same position in the circumferential direction of the roller 1. This ensures that only a few sensors 12, and in particular only one sensor, pass through the treatment gap at any given time, allowing multiple sensors 12 to share the same signal line. In the case of a spiral, all sensors 12 may be connected to the sensor data unit 21 via the same signal line.

A further development of the present invention involves mounting a position sensor 22 on one of the end faces 6a, 6b of the roller cylinder 2 to detect the roller's angle of rotation. The position sensor 22 is preferably an optical sensor.

The position sensor 22 and the sensor data unit 21 may be arranged on the same end face 6a, 6b and connected to each other via a data line 23. A transmission unit 24 on the same end face 6a, 6b can then transmit both data derived from the signals of the sensors 12 and data derived from the signals of the position sensor 22 to the evaluation unit. This has the advantage that no additional module needs to be installed, since all necessary components can be contained within the signal data unit.

A web processing machine may include a sensor roller and a counter-roller arranged parallel thereto, with a treatment gap between them, wherein each of the sensors 12 on the sensor roller can detect the pressure exerted on the sensor roller as it passes through the treatment gap. Based on the detection of the rotational angle of the sensor roller by the position sensor 22, the position in the circumferential direction relative to the treatment gap can be determined for each sensor. The sensors 12 may be arranged such that, as the rollers rotate, only one of the sensors 12 passes through the treatment gap at a time. The same applies if the web processing machine has a sensor roller with multiple counter rollers, wherein a first and a second treatment gap are present. Based on the detection of the rotation angle of the sensor roller by the position sensor 22, the position of each sensor in the circumferential direction relative to the first treatment gap and the second treatment gap can be determined. In this configuration as well, the sensors 12 can be arranged such that, as the rollers rotate, only one of the sensors 12 passes through a treatment gap at a time.

The position sensor 22 can reliably determine which treatment gap a sensor is currently passing through. Thus, the assignment of the sensors 12 to a treatment gap is unambiguous, and confusion is ruled out. This is particularly important when multiple counter-rollers are in contact with the sensor roller 1.

In an example according to the invention, a roller 1 was manufactured comprising a roller core 3, sensors 12, a shield, and a roller cover surface in that order. A film substrate with printed pressure sensors 12 and electrical conductors, adhered to the roller core 3, was used as the sensor layer 12, and aluminum foil adhered to the sensor film was used as the shielding 13.

In a comparative example, the same roller 1 was manufactured without aluminum foil.

The rollers were tested on a test bench, and pressure signals were recorded. The signals detected on the roller 1 of the exemplary embodiment of the invention showed significantly better quality, in particular improved clarity without noise, than those of the comparative example.

The following is a summary list of reference numerals and the corresponding structure used in the above description of the invention:
1 Roller
2 Roller Cylinder
3 Roller Core
4 Roller Cover
4a, 4b, 4n Roller Cover Layer
5 Outer Surface
6a, 6b End Face
7 Roller Axis, Rotational Axis
12 Plurality of Sensors
13 Shield
14 Insulating Layer
21 Sensor Data Unit
22 Position Sensor
23 Data Line
24 Transmission Unit

1. A roller for a web processing machine, the roller comprising:
a roller cylinder having a cylindrical roller core, a roller cover surrounding the roller core, and an outer surface;
the roller cover having at least one roller cover layer, and the roller cover having a plurality of sensors;
an electrically conductive shield between the plurality of sensors and the outer surface in the radial direction;
the roller core being electrically conductive and being in electrical contact with the electrically conductive shield.

2. The roller according to claim 1, wherein the plurality of sensors are pressure sensors.

3. The roller according to claim 1, wherein at least one of the plurality of sensors is arranged on the roller core or between two roller cover layers.

4. The roller according to claim 1, wherein the plurality of sensors are separated from the electrically conductive shield by an insulating layer.

5. The roller according to claim 1, wherein the plurality of sensors are each configured as a sensor layer arranged on the roller core, the roller cover layer, an insulating layer, or a sensor film.

6. The roller according to claim 1, wherein the plurality of sensors are printed.

7. The roller according to claim 1, wherein the electrically conductive shield has metal-containing materials or carbon-containing materials.

8. The roller according to claim 1, wherein the electrically conductive shield is a roller cover layer of the at least one roller cover layer and contains electrically conductive material, a shielding foil, a shielding mesh, or a shielding layer applied to the plurality of sensors or to an insulation on the plurality of sensors.

9. The roller according to claim 8, wherein the shielding layer is printed.

10. The roller according to claim 1, wherein:
the electrically conductive shield is a foil that extends axially beyond the roller cylinder and is electrically contacted with the roller core; or
the plurality of sensors are arranged between the roller core and an electrically conductive roller cover layer, and the roller core and the electrically conductive roller cover layer are in electrical contact between the plurality of sensors.

11. The roller according to claim 1, wherein signals generated by the plurality of sensors are transmitted via a signal line to a sensor data unit.

12. The roller according to claim 1, further comprising a position sensor for detecting a rotational angle of the roller, the position sensor being arranged on a first end-face of the roller.

13. The roller according to claim 12, wherein the position sensor and the sensor data unit are arranged on the first end face of the roller and are communicatively connected via a data line.

14. A web processing machine comprising:
a roller according to claim 1 configured as a sensor roller;
a counter-roller arranged parallel to the sensor roller;
a treatment gap between said sensor roller and said counter-roller;
each of the plurality of sensors of the sensor roller being configured to detect the pressure exerted on the sensor roller as it passes through the treatment gap.
